(19) United States
(12) Patent Application Publication
(10) Pub. No.: US 2007/0139070 A1
(43) Pub. Date: Jun. 21, 2007

(54) Buffer having predriver to help improve symmetry of rise and fall transitions in an output signal

(75) Inventors: Yanmei Tian, Sunnyvale, CA (US); Marlene Chan, San Jose, CA (US); Mohammed Atha, Sunnyvale, CA (US); Harry Muljono, San Ramon, CA (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/313,076

(22) Filed: Dec. 19, 2005

(51) Int. Cl. H03K 19/003

(52) U.S. Cl. 326/26

(57) ABSTRACT

For one disclosed embodiment, a driver may generate an output signal on a line. A predriver may receive an input signal and control the driver in response to the input signal to help improve symmetry of rise and fall transitions in the output signal. Other embodiments are also disclosed.

### FIELD

Embodiments described herein generally relate to signal buffers.

### BACKGROUND

FIG. 1 illustrates a prior art buffer 110. Buffer 110 receives an input signal and generates a corresponding output signal at a pad 112.

Buffer 110 includes a pull-up resistor 114 having an impedance Rₚᵤₗₗ₋ᵤₚ to couple pad 112 to a supply voltage V_{supply} node 115 and includes six pull-down stages 121, 122, 123, 124, 125, and 126 to selectively couple pad 112 to ground. A delay line 130 has six delays 131, 132, 133, 134, 135, and 136 coupled in series to receive the input signal and propagate the input signal along delay line 130. Delay line 130 generates at the outputs of delays 131-136 control signals with one delayed after another to sequentially activate pull-down stages 121-126 to form a fall transition in the output signal at pad 112 in response to a rise transition in the input signal and to sequentially deactivate pull-down stages 121-126 to form a rise transition in the output signal at pad 112 in response to a fall transition in the input signal. Delay line 130 deactivates pull-down stages 121-126 in the same sequential order as delay line 130 activates pull-down stages 121-126.

Each pull-down stage 121-126, as illustrated in pull-down stage 126, has multiple enable circuits, such as enable circuits 181 and 182, that may be selectively activated to enable a control signal from delay line 130 to selectively activate a corresponding pull-down n-channel metal oxide semiconductor field effect transistor (nMOSFET), such as nMOSFET 183 and 184, to couple pad 112 to ground. Each enable circuit, as illustrated in enable circuit 181, has a pass gate 186 that may be selectively activated to enable a control signal from delay line 130 to selectively activate a corresponding pull-down nMOSFET. Pass gate 186 is activated or deactivated in response to a corresponding enable signal input to the enable circuit and the inversion of the enable signal generated by an inverter 187. Also, a pull-down nMOSFET 188 may be selectively activated in response to the inverted enable signal to deactivate the corresponding pull-down nMOSFET. The strength of each pull-down stage 121-126 may therefore be set by selectively activating or deactivating each enable circuit of the pull-down stage.

To achieve a substantially linear fall transition in the output signal, the strength of pull-down stages 121-126 are set so the first pull-down stage 121 to be activated by delay line 130 is the weakest of the six pull-down stages and each pull-down stage 122-126 to be activated in sequential order is progressively stronger with the sixth pull-down stage 126 to be activated being the strongest. The desired impedance Rₙ for each pull-down stage n, where n refers to the nth pull-down stage in sequential order of activation by delay line 130, may be calculated from the following:
R₁//R₂// . . . //Rₙ=Rₚᵤₗₗ₋ᵤₚ*(V_{supply}−(n*(V_{supply}−Vₒₗ)/6))/(n*(V_{supply}−Vₒₗ)/6)
where Vₒₗ is a desired lower voltage level for the output signal.

Because pull-down stages 121-126 are deactivated in the same sequential order as they are activated, however, the rise transition in the output signal is non-linear and slower relative to the fall transition because weaker pull-down stages are deactivated first.

FIG. 2 illustrates a waveform 200 of an output signal generated from buffer 110. As illustrated in FIG. 2, waveform 200 has a substantially linear fall transition yet a slower, non-linear rise transition. The resulting disparity in rise and fall times and T_{co} mismatch can reduce timing margin which can limit output signal transmission speed.

### BRIEF DESCRIPTION OF THE DRAWINGS

Embodiments are illustrated by way of example and not limitation in the figures of the accompanying drawings, in which like references indicate similar elements and in which:

FIG. 1 illustrates a prior art buffer;

FIG. 2 illustrates a waveform of an output signal from the prior art buffer of FIG. 1;

FIG. 3 illustrates, for one embodiment, a block diagram of a buffer having a predriver to help improve symmetry of rise and fall transitions in an output signal;

FIG. 4 illustrates a waveform of an example output signal that may be generated from the buffer of FIG. 3 for one embodiment;

FIG. 5 illustrates, for one embodiment, a block diagram of circuitry for the buffer of FIG. 3;

FIG. 6 illustrates, for one embodiment, a flow diagram to generate an output signal using the buffer of FIG. 5;

FIG. 7 illustrates, for one embodiment, example circuitry for a predriver of the buffer of FIG. 5;

FIG. 8 illustrates, for another embodiment, example circuitry for a predriver of the buffer of FIG. 5;

FIG. 9 illustrates, for one embodiment, example circuitry for a driver of the buffer of FIG. 5; and

FIG. 10 illustrates, for one embodiment, a system comprising a processor having the buffer of FIG. 3.

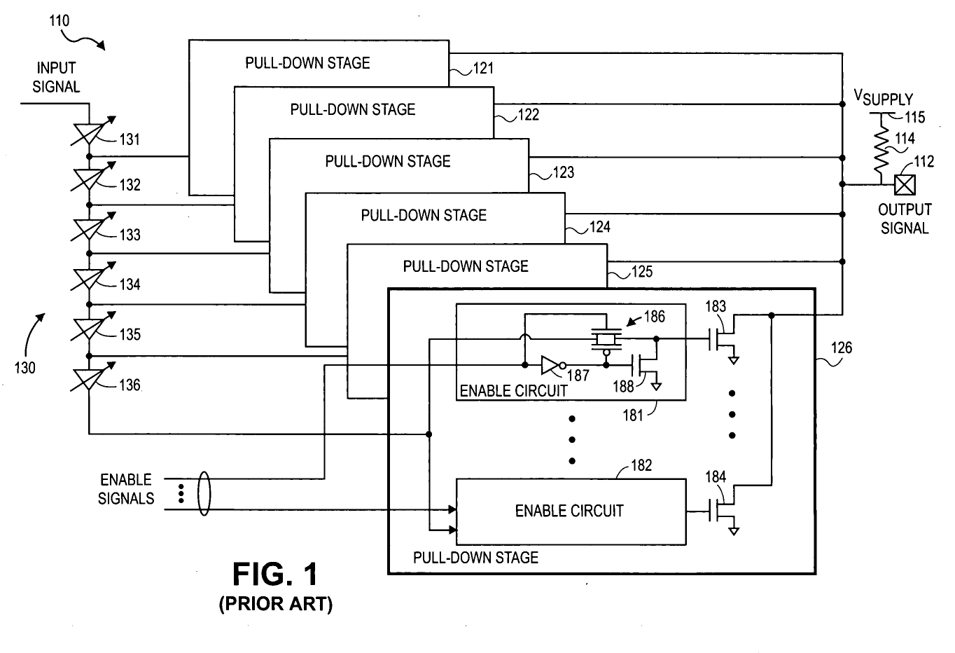

The figures of the drawings are not necessarily drawn to scale.

### DETAILED DESCRIPTION

The following detailed description sets forth example embodiments of apparatuses, methods, and systems relating to a buffer having a predriver to help improve symmetry of rise and fall transitions in an output signal. Features, such as structure(s), function(s), and/or characteristic(s) for example, are described with reference to one embodiment as a matter of convenience; various embodiments may be implemented with any suitable one or more described features.

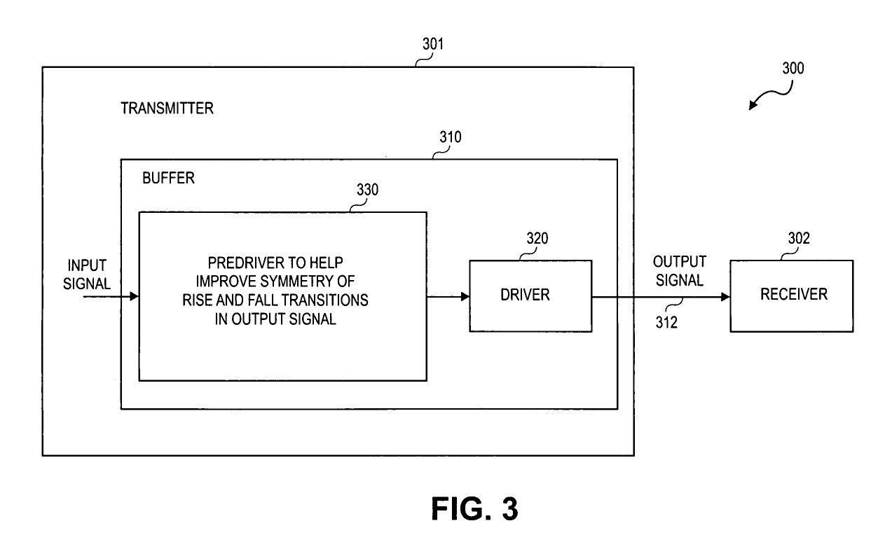

FIG. 3 illustrates, for one embodiment, a buffer 310 to receive an input signal and to generate an output signal on a line 312. Buffer 310 may comprise a driver 320 to generate the output signal on line 312. Buffer 310 may also comprise a predriver 330 to receive the input signal and to control driver 320 in response to the input signal to help improve symmetry of rise and fall transitions in the output signal. Driver 320 and predriver 330 may include any suitable circuitry.

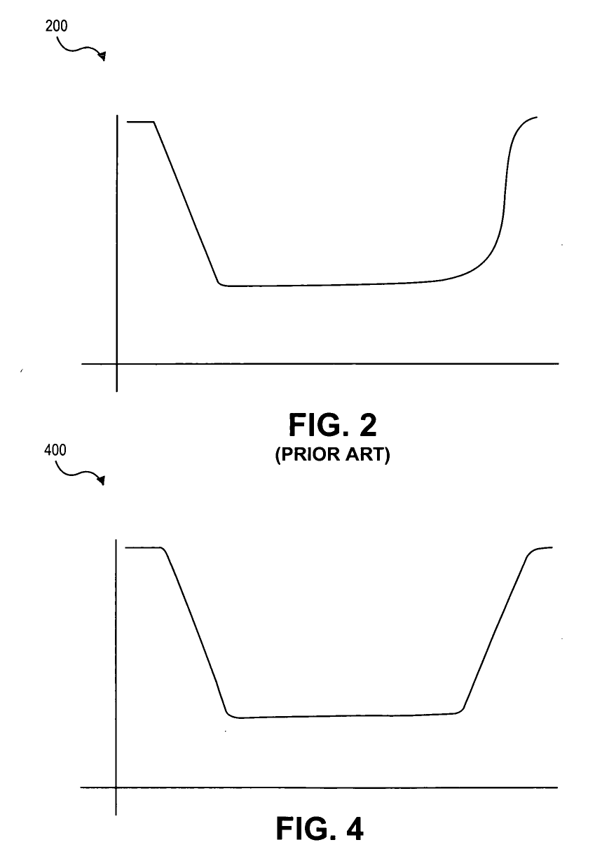

FIG. 4 illustrates a waveform 400 of an example output signal that may be generated from the buffer of FIG. 3 for one embodiment. Relative to waveform 200 of FIG. 2, for example, waveform 400 has improved symmetry in rise and fall transitions.

Improving symmetry of rise and fall transitions in the output signal for one embodiment may help provide increased control over both rise and fall transitions in the output signal. Improving symmetry of rise and fall transitions in the output signal for one embodiment may help provide improved edge rate control. Improving symmetry of rise and fall transitions in the output signal for one embodiment may help increase timing margin. Improving symmetry of rise and fall transitions in the output signal for one embodiment may help allow increased output signal transmission speed.

Buffer 310 for one embodiment may generate an output signal corresponding to the received input signal. Buffer 310 for one embodiment may form a transition in the output signal in response to a transition in the input signal. Buffer 310 for one embodiment may form a rise transition, for example, in the output signal in response to a fall transition, for example, in the input signal. Buffer 310 for one embodiment may form a fall transition, for example, in the output signal in response to a rise transition, for example, in the input signal. Buffer 310 may form rise and fall transitions in the output signal in accordance with any suitable waveform. Buffer 310 for one embodiment may form in the output signal, for example, a substantially linear rise transition having any suitable edge rate or slope and a substantially linear fall transition having any suitable edge rate or slope.

Driver 320 for one embodiment may have pull-up circuitry to couple line 312 to a first node and pull-down circuitry to selectively couple line 312 to a second node to generate the output signal on line 312. Predriver 330 for one embodiment may control pull-down circuitry in response to the input signal to generate the output signal and to help improve symmetry of rise and fall transitions in the output signal. Predriver 330 for one embodiment may activate pull-down circuitry in response to a transition, such as a rise transition for example, in the input signal to form a fall transition in the output signal. Predriver 330 for one embodiment may deactivate pull-down circuitry in response to a transition, such as a fall transition for example, in the input signal to form a rise transition in the output signal. Predriver 330 for one embodiment may help improve symmetry of rise and fall transitions in the output signal by controlling how pull-down circuitry is activated and deactivated.

Buffer 310 may be used in any suitable application. Buffer 310 for one embodiment, as illustrated in FIG. 3, may generally be used as part of a transmitter 301 to transmit an output signal over line 312 to a receiver 302 coupled to receive the output signal. Although described and illustrated as including one buffer 310, transmitter 301 for one embodiment may include any suitable number of buffers similar to buffer 310 to transmit output signals to receiver 302 and/or to any other suitable receiver. Transmitter 301 and receiver 302 may form at least a portion of system 300.

Transmitter 301 may comprise any suitable circuitry to use buffer 310 to transmit an output signal to receiver 302. Transmitter 301 may comprise, for example, circuitry for a processor, memory, and/or controller, such as a memory controller or input/output (I/O) controller for example. Receiver 302 may comprise any suitable circuitry to receive an output signal from buffer 310 of transmitter 301. Receiver 302 may comprise, for example, circuitry for a processor, memory, and/or controller, such as a memory controller or input/output (I/O) controller for example.

Buffer 310 for one embodiment may be implemented in an integrated circuit that forms at least a portion of transmitter 301. Receiver 302 for one embodiment may include at least one integrated circuit coupled to receive the output signal from buffer 310.

Predriver and Driver

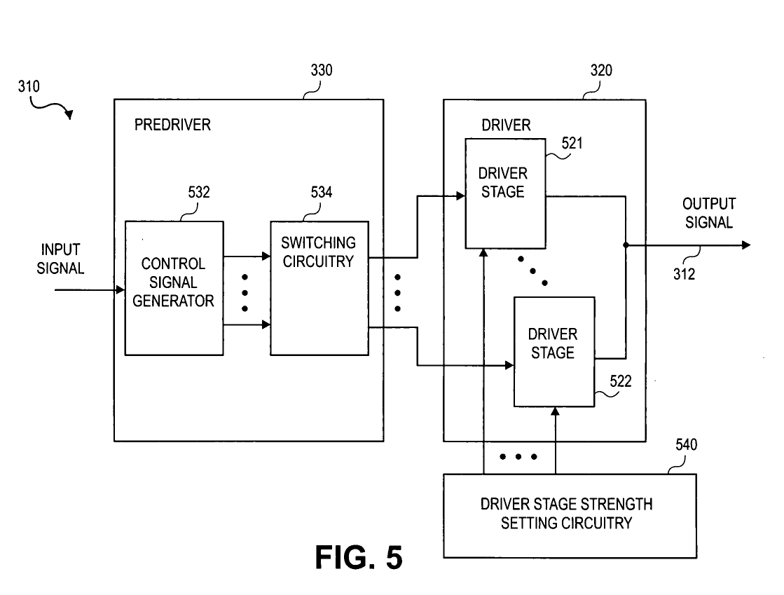

FIG. 5 illustrates, for one embodiment, circuitry for driver 320 and predriver 330 of buffer 310 of FIG. 3.

As illustrated in FIG. 5, driver 320 for one embodiment may include multiple driver stages, such as driver stages 521 and 522 for example, coupled to generate an output signal on line 312. Driver 320 may include any suitable number of driver stages, and such driver stages may include any suitable circuitry. One or more driver stages for one embodiment may be selectively activated to couple line 312 to a supply node and deactivated to decouple line 312 from the supply node. One or more driver stages for one embodiment may include pull-down circuitry to selectively couple line 312 to a supply node having a lower supply voltage, such as ground for example.

A driver stage may or may not have the same strength as another driver stage. One or more driver stages for one embodiment may have a programmable strength. Such driver stage(s) for one embodiment may optionally be coupled to receive one or more strength setting signals from driver stage strength setting circuitry 540. Driver stage strength setting circuitry 540 for one embodiment may include one or more registers that may be programmed to store desired strength setting signals. The strength of a driver stage may be programmed, for example, to help form a rise and/or fall transition in the output signal in accordance with a desired waveform. The strength of a driver stage for one embodiment may be programmed to help form in the output signal a substantially linear rise transition having any suitable edge rate or slope and a substantially linear fall transition having any suitable edge rate or slope.

Predriver 330 for one embodiment may be coupled to activate and deactivate multiple driver stages in accordance with an order to help better control transitions in the output signal. Predriver 330 for one embodiment may activate multiple driver stages of driver 320 in accordance with any suitable first order to form a first transition, such as a fall transition for example, in the output signal and deactivate multiple driver stages of driver 320 in accordance with any suitable second order different from the first order to form a second transition, such as a rise transition for example, in the output signal. Predriver 330 for one embodiment may activate one driver stage of driver 320 at a time in accordance with the first order. Predriver 330 for one embodiment may deactivate one driver stage of driver 320 at a time in accordance with the second order. The second order for one embodiment may be a reverse order of the first order. Deactivating multiple driver stages in a reverse order from the order in which such driver stages are activated for one embodiment may help improve symmetry of rise and fall transitions in an output signal.

Predriver 330 for one embodiment may include a control signal generator 532 and switching circuitry 534.

Control signal generator 532 for one embodiment may be coupled to receive an input signal to generate multiple control signals in response to the input signal. Control signal generator 532 may include any suitable circuitry. Control signal generator 532 for one embodiment may include one or more delay lines to generate control signals that are delayed relative to one or more other control signals. Control signal generator 532 for one embodiment may delay control signals by any suitable amount of time to help form a rise and/or fall transition in the output signal in accordance with a desired waveform. Control signal generator 532 for one embodiment may delay control signals by any suitable amount of time to help form in the output signal a substantially linear rise transition having any suitable edge rate or slope and a substantially linear fall transition having any suitable edge rate or slope.

Switching circuitry 534 for one embodiment may be coupled to receive control signals to control driver stages of driver 320 based on received control signals. Switching circuitry 534 may include any suitable circuitry. Switching circuitry 534 for one embodiment may be coupled to selectively activate and deactivate driver stages based on received control signals. Switching circuitry 534 for one embodiment may be coupled to receive the input signal to selectively control driver stages in response to the input signal.

Control signal generator 532 and switching circuitry 534 for one embodiment may together activate multiple driver stages in accordance with a first order in response to a first transition, such as a rise transition for example, in the input signal and deactivate multiple driver stages in accordance with a second order different from the first order in response to a second transition, such as a fall transition for example, in the input signal.

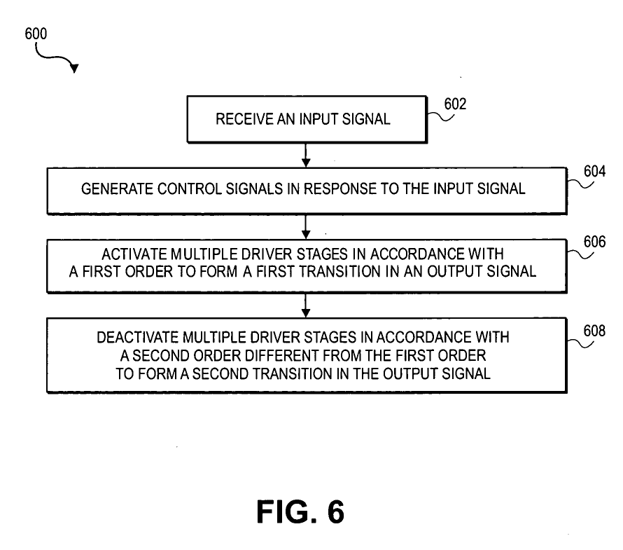

FIG. 6 illustrates, for one embodiment, a flow diagram 600 to generate an output signal using buffer 310 of FIG. 5. For block 602 of FIG. 6, an input signal is received by predriver 330. Control signals are generated for block 604 by control signal generator 532 of predriver 330 in response to the input signal. For block 606, multiple driver stages of driver 320 are activated by switching circuitry 534 of predriver 330 in accordance with a first order to form a first transition in an output signal. For block 608, multiple driver stages of driver 320 are deactivated by switching circuitry 534 in accordance with a second order different from the first order to form a second transition in the output signal.

Example Predriver Circuitry

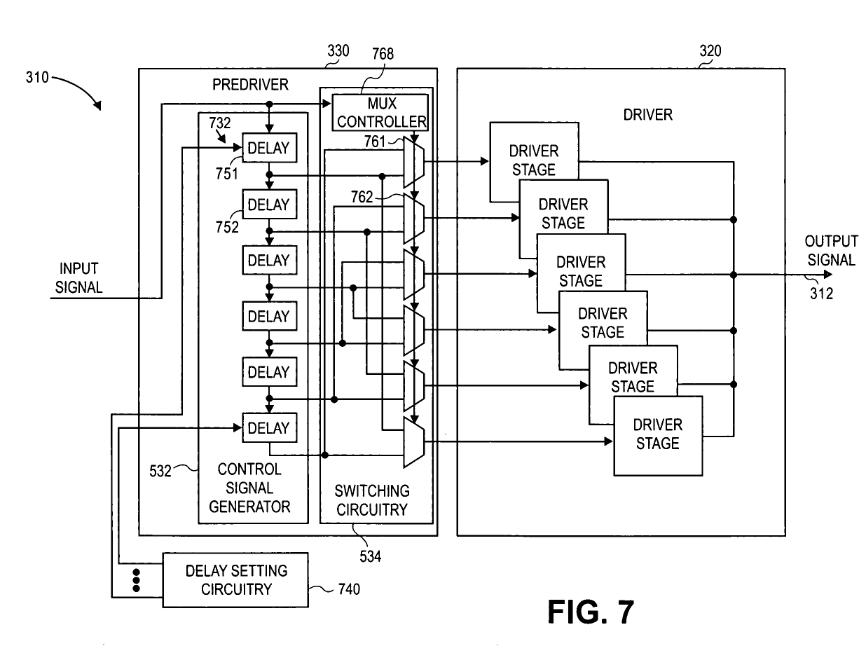

FIG. 7 illustrates, for one embodiment, example circuitry for predriver 330 of buffer 310 of FIG. 5.

Control signal generator 532 for one embodiment may include a delay line, such as delay line 732 for example, coupled to receive an input signal for buffer 310 to generate multiple control signals delayed relative to one or more other control signals in response to the input signal. The delay line for one embodiment may include one or more delays. The delay line for one embodiment may include multiple delays coupled in series, that is with one or more delays coupled to receive a signal output from a prior delay in the delay line. The delay line for one embodiment may have multiple nodes at which control signals may be generated. For one embodiment, one or more control signals may be generated at an output node of a corresponding delay. The delay line for one embodiment may generate control signals with one delayed after another. The delay line for one embodiment may be coupled to receive the input signal and propagate the input signal along the delay line to generate control signals.

As one example, delay line 732 includes multiple delays, such as delays 751 and 752 for example, coupled in series to receive an input signal for buffer 310 and propagate the input signal along delay line 732 to generate a control signal at an output node of each delay. A control signal generated at an output node of one delay may then be delayed relative to a control signal generated at an output node of a prior delay in delay line 732. Although illustrated in FIG. 7 with delay line 732 for one embodiment having six delays to generate six control signals at an output node of a corresponding delay, control signal generator 532 for one embodiment may include a delay line having any suitable number of one or more delays to generate any suitable number of control signals from the input signal and/or from an output node of any suitable one or more delays.

A delay may be implemented in any suitable manner to delay by any suitable amount of time a transition in a signal received by the delay. One or more delays for one embodiment may have a programmable delay. Such delay(s) for one embodiment may optionally be coupled to receive one or more delay setting signals from delay setting circuitry 740. Delay setting circuitry 740 for one embodiment may include one or more registers that may be programmed to store desired delay setting signals. The delay of a delay may be programmed, for example, to help form a rise and/or fall transition in the output signal in accordance with a desired waveform. The delay of a delay for one embodiment may be programmed to help form in the output signal a substantially linear rise transition having any suitable edge rate or slope and a substantially linear fall transition having any suitable edge rate or slope.

Switching circuitry 534 for one embodiment may include multiple multiplexers, such as multiplexers 761 and 762 for example, having inputs coupled to receive control signals to selectively control driver stages of driver 320 based on received control signals. One or more multiplexers for one embodiment may have inputs coupled to receive different control signals to selectively control a corresponding driver stage of driver 320. A multiplexer for one embodiment may be controlled to selectively output one of the received control signals to control a corresponding driver stage. A multiplexer for one embodiment may be coupled to selectively activate and deactivate a corresponding driver stage. Although illustrated in FIG. 7 with switching circuitry 534 for one embodiment having six multiplexers to control six driver stages of driver 320, switching circuitry 534 for one embodiment may include any suitable number of multiplexers to control any suitable number of driver stages of driver 320.

Multiple multiplexers for one embodiment may be controlled to output a corresponding first received control signal when driver stages of driver 320 are to be activated and to output a corresponding second received control signal when driver stages are to be deactivated. Multiple multiplexers for one embodiment may be controlled to output a corresponding first received control signal when an input signal received by buffer 310 has a first transition, such as a rise transition for example, and to output a corresponding second received control signal when the input signal has a second transition, such as a fall transition for example. Switching circuitry 534 for one embodiment may include a MUX controller 768 to control multiple multiplexers to selectively output control signals to control driver stages of driver 320. MUX controller 768 for one embodiment may generate one or more MUX control signals in response to an input signal for buffer 310 to control multiple multiplexers. Switching circuitry 534 for one embodiment may use the input signal itself to control one or more multiplexers.

For one embodiment where control signal generator 532 may generate control signals delayed relative to one or more other control signals, driver stages of driver 320 for one embodiment may be activated in accordance with a first order defined by which multiplexer is controlled to output which control signal when driver stages are to be activated and may be deactivated in accordance with a second order defined by which multiplexer is controlled to output which control signal when driver stages are to be deactivated. As illustrated in FIG. 7, multiple multiplexers for one embodiment may be coupled to receive control signals and controlled to activate driver stages in a first order and deactivate driver stages in a second order that is a reverse order of the first order.

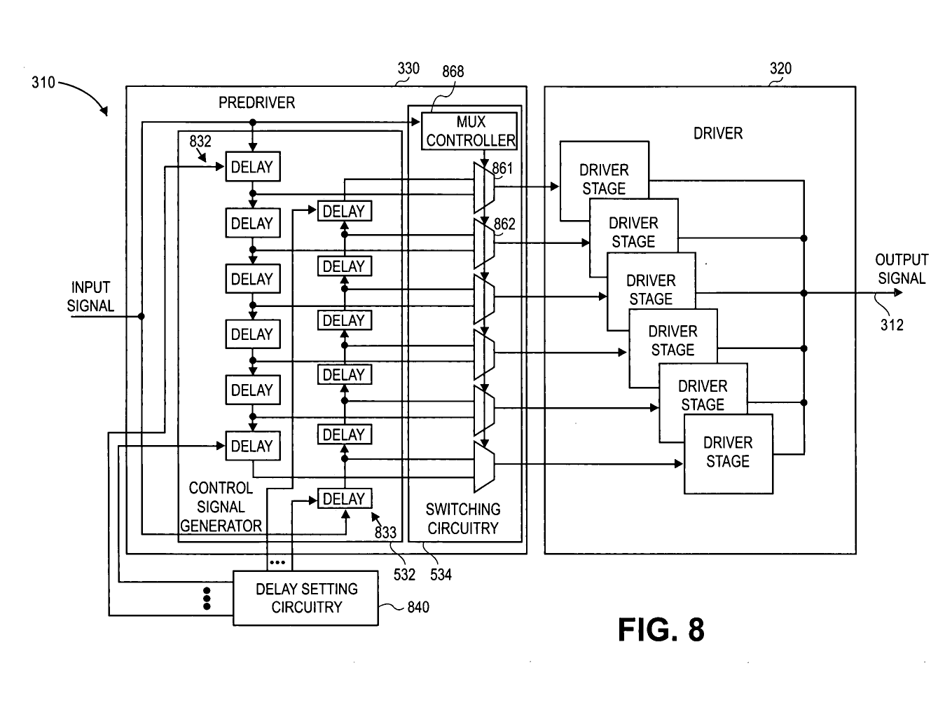

FIG. 8 illustrates, for another embodiment, example circuitry for predriver 330 of buffer 310 of FIG. 5.

Control signal generator 532 for one embodiment may include two delay lines, such as delay lines 832 and 833 for example. The above description of a delay line for control signal generator 532 may similarly apply to each of two delay lines for control signal generator 532 to the extent that description is not inconsistent with the description of the two delay lines.

One of the two delay lines for one embodiment may be coupled to receive an input signal for buffer 310 to generate multiple activation control signals delayed relative to one or more other activation control signals in response to the input signal. The other delay line for one embodiment may be coupled to receive the input signal to generate multiple deactivation control signals delayed relative to one or more other deactivation control signals in response to the input signal. Although illustrated in FIG. 8 with delay lines 832 and 833 for one embodiment each having six delays to generate six activation or deactivation control signals at an output node of a corresponding delay, control signal generator 532 for one embodiment may include delay lines each having any suitable number of one or more delays to generate any suitable number of activation or deactivation control signals from the input signal and/or from an output node of any suitable one or more delays. The delay lines may or may not be similarly implemented.

One or more delays for either or both delay lines for one embodiment may have a programmable delay. Such delay(s) for one embodiment may optionally be coupled to receive one or more delay setting signals from delay setting circuitry 840. Delay setting circuitry 840 for one embodiment may include one or more registers that may be programmed to store desired delay setting signals.

Switching circuitry 534 for one embodiment may include multiple multiplexers, such as multiplexers 861 and 862 for example. One or more multiplexers for one embodiment may have inputs coupled to receive a corresponding activation control signal and a corresponding deactivation control signal to selectively control a corresponding driver stage of driver 320. A multiplexer for one embodiment may be controlled to selectively output a received activation control signal or a received deactivation control signal and may be coupled to selectively activate and deactivate a corresponding driver stage. Although illustrated in FIG. 8 with switching circuitry 534 for one embodiment having six multiplexers to control six driver stages of driver 320, switching circuitry 534 for one embodiment may include any suitable number of multiplexers to control any suitable number of driver stages of driver 320.

Multiple multiplexers for one embodiment may be controlled to output a corresponding received activation control signal when driver stages of driver 320 are to be activated and to output a corresponding received deactivation control signal when driver stages are to be deactivated. Multiple multiplexers for one embodiment may be controlled to output a corresponding received activation control signal when an input signal received by buffer 310 has a first transition, such as a rise transition for example, and to output a corresponding received deactivation control signal when the input signal has a second transition, such as a fall transition for example. Switching circuitry 534 for one embodiment may include a MUX controller 868 to control multiple multiplexers to selectively output activation and deactivation control signals to control driver stages of driver 320. MUX controller 868 for one embodiment may generate one or more MUX control signals in response to an input signal for buffer 310 to control multiple multiplexers. Switching circuitry 534 for one embodiment may use the input signal itself to control one or more multiplexers.

For one embodiment where control signal generator 532 may generate activation control signals delayed relative to one or more other activation control signals, driver stages of driver 320 for one embodiment may be activated in accordance with a first order defined by which multiplexer is controlled to output which activation control signal when driver stages are to be activated. For one embodiment where control signal generator 532 may generate deactivation control signals delayed relative to one or more other deactivation control signals, driver stages of driver 320 for one embodiment may be deactivated in accordance with a second order defined by which multiplexer is controlled to output which deactivation control signal when driver stages are to be deactivated. As illustrated in FIG. 8, multiple multiplexers for one embodiment may be coupled to receive activation and deactivation control signals and controlled to activate driver stages in a first order and deactivate driver stages in a second order that is a reverse order of the first order.

Example Driver Circuitry

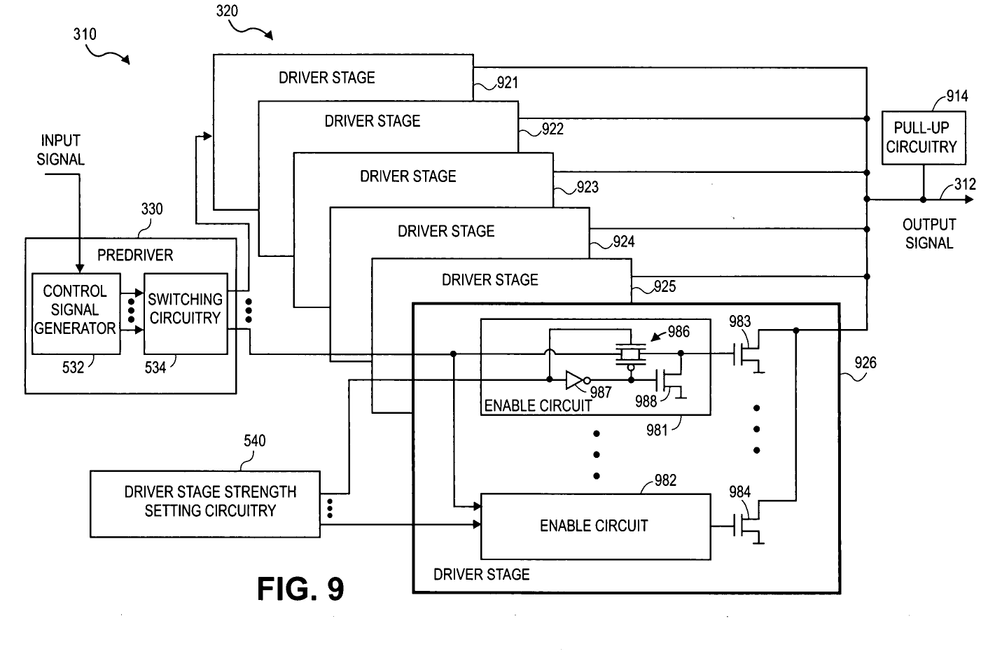

FIG. 9 illustrates, for one embodiment, example circuitry for driver 320 of buffer 310 of FIG. 5.

Driver 320 for one embodiment may have pull-up circuitry 914 to couple line 312 to a supply node having a higher supply voltage V_{supply} and may have multiple driver stages, such as driver stages 921, 922, 923, 924, 925, and 926 for example, to selectively couple line 312 to a supply node having a lower supply voltage, such as ground for example. Although illustrated as including six driver stages 921-926, driver 320 may include any suitable number of driver stages.

Pull-up circuitry 914 may include any suitable circuitry and have any suitable impedance Rₚᵤₗₗ₋ᵤₚ. Pull-up circuitry 914 for one embodiment may include a resistor coupled between line 312 and a higher supply node. Such a resistor may be implemented in any suitable manner. Pull-up circuitry 914 for one embodiment may be distributed among multiple driver stages to form a portion of such driver stages.

Driver stages of driver 320 for one embodiment may include any suitable pull-down device or circuitry to selectively couple line 312 to a lower supply node. One or more driver stages for one embodiment may include one or more pull-down transistors coupled to receive a control signal from predriver 330 to selectively couple line 312 to a lower supply node in response to the control signal. A driver stage may include any suitable number of one or more pull-down transistors. Any suitable transistor may be used for a driver stage such as, for example, a suitable field effect transistor (FET).

One or more driver stages for one embodiment may include one or more enable circuits that may be selectively activated to enable a control signal from predriver 330 to control a corresponding pull-down transistor. A driver stage may include any suitable number of one or more enable circuits, and such enable circuit(s) may include any suitable circuitry. One or more enable circuits of a driver stage for one embodiment may be coupled to receive a corresponding enable signal from driver stage strength setting circuitry 540 to selectively enable a control signal from predriver 330 to control a corresponding pull-down transistor in response to the enable signal. One or more enable circuits of a driver stage may be selectively activated or deactivated to set a strength of the driver stage.

As one example, driver stage 926 of FIG. 9 may include multiple enable circuits, such as enable circuits 981 and 982 for example, to selectively enable a control signal from predriver 330 to control a corresponding pull-down transistor, such as transistor 983 and 984 for example. Enable circuit 981, for example, for one embodiment may include a pass gate 986 coupled to receive a control signal from predriver 330 to selectively transmit the control signal to corresponding pull-down transistor 983 in response to a corresponding enable signal. Pass gate 986 for one embodiment may be coupled to be activated or deactivated in response to the enable signal and the inversion of the enable signal generated by an inverter 987. Enable circuit 981 for one embodiment may also include a pull-down transistor 988 coupled to be selectively activated in response to the inverted enable signal to deactivate corresponding pull-down transistor 983.

The strength of a driver stage may be programmed, for example, to help form a rise and/or fall transition in the output signal in accordance with a desired waveform. The strength of a driver stage for one embodiment may be programmed to help form in the output signal a substantially linear rise transition having any suitable edge rate or slope and a substantially linear fall transition having any suitable edge rate or slope. For one embodiment, the strength of driver stages may be programmed to help reduce a voltage signal on line 312 by substantially the same amount of voltage when an additional driver stage is activated. The delay in activating such additional driver stages for one embodiment may be set or programmed to be substantially the same to help form a substantially linear fall transition. For one embodiment, the strength of driver stages may be programmed to help increase a voltage signal on line 312 by substantially the same amount of voltage when an additional driver stage is deactivated. The delay in deactivating such additional driver stages for one embodiment may be set or programmed to be substantially the same to help form a substantially linear rise transition.

For one embodiment, the strength of driver stages may be programmed to help achieve a desired impedance Rₙ for each driver stage n of N driver stages, where n refers to the nth driver stage in sequential order of activation, for example, to help reduce a voltage signal on line 312 by substantially the same amount of voltage when an additional driver stage is activated. The impedance Rₙ may be calculated from the following:
R₁//R₂// . . . //Rₙ=Rₚᵤₗₗ₋ᵤₚ*(V_{supply}−(n*(V_{supply}−Vₒₗ)/6))/(n*(V_{supply}−Vₒₗ)/6)
where Vₒₗ is a desired lower voltage level for the output signal.

For one embodiment, the strength of driver stages may be programmed to help change a voltage signal on line 312 by a varied amount of voltage when an additional driver stage is activated or deactivated. The delay in activating or deactivating such additional driver stages for one embodiment may be set or programmed to be varied accordingly to help form a substantially linear transition.

Example System

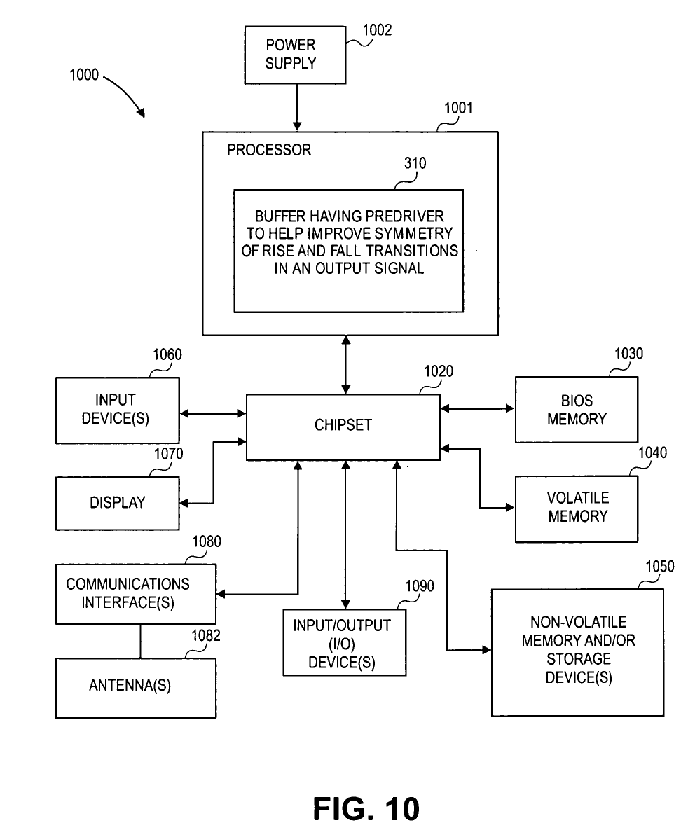

Buffer 310 for one embodiment may be used in any suitable integrated circuit. Buffer 310 for one embodiment may be used in an integrated circuit designed to form at least a portion of a processor. Such a processor may be used in any suitable system. Buffer 310 for one embodiment may be used in a processor 1001 of an example system 1000 as illustrated in FIG. 10. Processor 1001 for one embodiment may use buffer 310 to transmit a signal to a chipset 1020, for example.

Processor 1001 for one embodiment may be coupled to receive power from a power supply 1002 to provide power to at least buffer 310. Power supply 1002 for one embodiment may include a battery. Power supply 1002 for one embodiment may include an alternating current to direct current (AC-DC) converter. Power supply 1002 for one embodiment may include a DC-DC converter. Power supply 1002 for one embodiment may include one or more voltage regulators to help supply power to processor 1001.

System 1000 for one embodiment may also comprise chipset 1020 coupled to processor 1001, a basic input/output system (BIOS) memory 1030 coupled to chipset 1020, volatile memory 1040 coupled to chipset 1020, non-volatile memory and/or storage device(s) 1050 coupled to chipset 1020, one or more input devices 1060 coupled to chipset 1020, a display 1070 coupled to chipset 1020, one or more communications interfaces 1080 coupled to chipset 1020, and/or one or more other input/output (I/O) devices 1090 coupled to chipset 1020.

Chipset 1020 for one embodiment may include any suitable interface controllers to provide for any suitable communications link to processor 1001 and/or to any suitable device or component in communication with chipset 1020.

Chipset 1020 for one embodiment may include a firmware controller to provide an interface to BIOS memory 1030. BIOS memory 1030 may be used to store any suitable system and/or video BIOS software for system 1000. BIOS memory 1030 may include any suitable non-volatile memory, such as a suitable flash memory for example. BIOS memory 1030 for one embodiment may alternatively be included in chipset 1020.

Chipset 1020 for one embodiment may include one or more memory controllers to provide an interface to volatile memory 1040. Volatile memory 1040 may be used to load and store data and/or instructions, for example, for system 1000. Volatile memory 1040 may include any suitable volatile memory, such as suitable dynamic random access memory (DRAM) for example.

Chipset 1020 for one embodiment may include a graphics controller to provide an interface to display 1070. Display 1070 may include any suitable display, such as a cathode ray tube (CRT) or a liquid crystal display (LCD) for example. The graphics controller for one embodiment may alternatively be external to chipset 1020.

Chipset 1020 for one embodiment may include one or more input/output (I/O) controllers to provide an interface to non-volatile memory and/or storage device(s) 1050, input device(s) 1060, communications interface(s) 1080, and/or I/O devices 1090.

Non-volatile memory and/or storage device(s) 1050 may be used to store data and/or instructions, for example. Non-volatile memory and/or storage device(s) 1050 may include any suitable non-volatile memory, such as flash memory for example, and/or may include any suitable non-volatile storage device(s), such as one or more hard disk drives (HDDs), one or more compact disc (CD) drives, and/or one or more digital versatile disc (DVD) drives for example.

Input device(s) 1060 may include any suitable input device(s), such as a keyboard, a mouse, and/or any other suitable cursor control device.

Communications interface(s) 1080 may provide an interface for system 1000 to communicate over one or more networks and/or with any other suitable device. Communications interface(s) 1080 may include any suitable hardware and/or firmware. Communications interface(s) 1080 for one embodiment may include, for example, a network adapter, a wireless network adapter, a telephone modem, and/or a wireless modem. For wireless communications, communications interface(s) 1080 for one embodiment may use one or more antennas 1082.

I/O device(s) 1090 may include any suitable I/O device(s) such as, for example, an audio device to help convert sound into corresponding digital signals and/or to help convert digital signals into corresponding sound, a camera, a camcorder, a printer, and/or a scanner.

Although described as residing in chipset 1020, one or more controllers of chipset 1020 may be integrated with processor 1001, allowing processor 1001 to communicate with one or more devices or components directly. As one example, one or more memory controllers for one embodiment may be integrated with processor 1001, allowing processor 1001 to communicate with volatile memory 1040 directly.

In the foregoing description, example embodiments have been described. Various modifications and changes may be made to such embodiments without departing from the scope of the appended claims. The description and drawings are, accordingly, to be regarded in an illustrative rather than a restrictive sense.

What is claimed is:

1. An apparatus comprising:
a driver to generate an output signal on a line; and
a predriver to receive an input signal and to control the driver in response to the input signal to help improve symmetry of rise and fall transitions in the output signal.

2. The apparatus of claim 1, wherein the driver includes multiple driver stages to generate the output signal.

3. The apparatus of claim 2, wherein the predriver is to activate multiple driver stages in accordance with a first order to form a first transition in the output signal and to deactivate multiple driver stages in accordance with a second order different from the first order to form a second transition in the output signal.

4. The apparatus of claim 3, wherein the second order is a reverse order of the first order.

5. The apparatus of claim 3, wherein the predriver includes a control signal generator to generate multiple control signals in response to the input signal and switching circuitry to selectively activate and deactivate driver stages based on control signals.

6. The apparatus of claim 5, wherein the control signal generator includes one or more delay lines to generate multiple control signals delayed relative to one or more other control signals in response to the input signal.

7. The apparatus of claim 5, wherein the switching circuitry includes multiple multiplexers and wherein a multiplexer has inputs to receive different control signals to selectively control a corresponding driver stage.

8. The apparatus of claim 3, wherein the predriver includes a first delay line to generate multiple activation control signals in response to the input signal, a second delay line to generate multiple deactivation control signals in response to the input signal, and switching circuitry to selectively activate and deactivate driver stages based on activation and deactivation control signals.

9. The apparatus of claim 8, wherein the switching circuitry includes multiple multiplexers and wherein a multiplexer has inputs to receive an activation control signal and a deactivation control signal to selectively control a corresponding driver stage.

10. The apparatus of claim 1, wherein the driver includes pull-up circuitry to couple the line to a first node and pull-down circuitry to selectively couple the line to a second node to generate the output signal on the line.

11. The apparatus of claim 2, wherein a driver stage includes pull-down circuitry to selectively couple the line to a node.

12. The apparatus of claim 2, wherein one or more driver stages have a programmable strength.

13. A method comprising:
receiving an input signal; and
controlling a driver in response to the input signal to help improve symmetry of rise and fall transitions in an output signal.

14. The method of claim 13, wherein controlling a driver includes activating multiple driver stages of the driver in accordance with a first order to form a first transition in the output signal and deactivating multiple driver stages of the driver in accordance with a second order different from the first order to form a second transition in the output signal.

15. The method of claim 14, wherein controlling a driver includes generating control signals in response to the input signal and selectively activating and deactivating driver stages based on control signals.

16. The method of claim 15, wherein generating control signals includes propagating the input signal along one or more delay lines to generate multiple control signals delayed relative to one or more other control signals.

17. A system comprising:
a battery; and
an integrated circuit coupled to receive power from the battery, the integrated circuit including a driver to generate an output signal on a line and a predriver to receive an input signal and to control the driver in response to the input signal to help improve symmetry of rise and fall transitions in the output signal.

18. The system of claim 17, wherein the predriver is to activate multiple driver stages of the driver in accordance with a first order to form a first transition in the output signal and to deactivate multiple driver stages of the driver in accordance with a second order different from the first order to form a second transition in the output signal.

19. The system of claim 18, wherein the predriver includes a control signal generator to generate multiple control signals in response to the input signal and switching circuitry to selectively activate and deactivate driver stages based on control signals.

20. The system of claim 19, wherein the control signal generator includes one or more delay lines to generate multiple control signals delayed relative to one or more other control signals in response to the input signal.

21. The system of claim 17, wherein the integrated circuit forms at least a portion of a processor.
